(19) United States
(12) Patent Application Publication
(10) Pub. No.: US 2026/0316172 A1
(43) Pub. Date: Oct. 15, 2026

(54) METHOD AND DEVICE FOR INFLUENCING A BONDING WAVE DURING BONDING

(71) Applicant: EV GROUP E. THALLNER GMBH, St. Florian am Inn (AT)

(72) Inventors: Jurgen BURGGRAF, St. Florian am Inn (AT); Andreas FEHKUHRER, St. Florian am Inn (AT)

(73) Assignee: EV GROUP E. THALLNER GMBH, St. Florian am Inn (AT)

(21) Appl. No.: 19/104,321

(22) PCT Filed: Sep. 2, 2022
(86) PCT No.: PCT/EP2022/074470

§ 371 Date: Feb. 17, 2025

(51) Int. Cl. B23K 1/08; B23K 101/40; H10P 72/00; H10W 80/00

(52) U.S. Cl. CPC B23K 1/085; H10P 72/0438; H10W 80/301; B23K 2101/40

(57) ABSTRACT

The invention relates to a method and a device for influencing a bonding wave during the bonding of substrates.

### FIELD OF THE INVENTION

The invention relates to a method and a device for influencing a bonding wave during the bonding of substrates. In addition, the invention relates to a method and a device for bonding with a substrate holder comprising at least one zone. Such zones are essential in some devices and methods for the individual processing, fixing and bonding of the substrate with other substrates or substrate stacks.

### BACKGROUND OF THE INVENTION

In the prior art, there are a plurality of publications, in which substrate holders for the fixing of substrates are described. Some of these substrate holders are used for the connection process of two substrates, the so-called bonding. So-called fusion and direct bonding is of particular importance in bonding processes. In fusion bonding, two substrates are bonded together only with the aid of their hydrophobic or hydrophilic substrate surface properties. In a first process step, the so-called pre-bonding, the contacting of the two substrates takes place at an, in particular, centric point. After the contacting, the fixing of the at least one, in particular the upper, substrate is released, so that the two substrates are bonded together along their substrate surfaces facing one another. The bonding process takes place by means of an advancing bonding wave which, starting from the contact point, is propagated outwards towards the periphery of the two substrates. After this bonding process, a separation of the two substrates with suitable methods and devices would still be conceivable after this bonding process. A separation is necessary, when it is found the substrates have not been bonded together in the optimum manner. The substrates have an untreated substrate surface. In most cases, the substrates have already been processed and comprise different structures. Switching circuits (engl.: Integrated circuits), microprocessors, LEDs, MEMS etc., for example, are conceivable. The structures should then be aligned with the structures on a second substrate and bonded with the latter. Above all, it is important that each individual structure of the first substrate must be correctly aligned and bonded to the structure present on the second substrate lying opposite.

After the production of the pre-bond, a thermal treatment of the produced substrate stack usually takes place in order to increase the adhesive strength between the two substrate surfaces. After the completion of this thermal treatment, one speaks of a fusion or permanent bond. From this time onwards, the two substrates can no longer be separated from one another free from destruction.

As a result of the advancing bonding wave, individual substrate areas can become distorted in the vicinity of the bonding wave, such that the alignment accuracy between the structures lying opposite one another is no longer present. In particular, a number of such distortions can even lead to a global distortion, which increases towards the periphery, in particular starting from the centre. In extreme cases, the distortions can even be anisotropic, i.e. direction-dependent.

The industry has thus developed a plurality of substrate holders, the aim of which consists in influencing the bonding wave. A control or regulation preferably takes place by means of fixing elements, with the aid of which the substrates can be fixed to the substrate holder. For example, publications WO2017162272A1, WO2018028801A1 or WO2019057286A1 describe possible ways of influencing the bonding wave by means of the zones of the zone substrate holder. A zone is understood to mean the area, which comprises at least one, possibly also a plurality of fixing elements. The zones can usually be physically separated from one another, but also just regions in which the fixing elements, according to a predefined plan, are switched.

In particular, a substrate holder can also comprise only a single zone, in which a plurality of fixing elements are generally present. Substrate holders with a plurality of zones, separated from one another by separating walls, are however particularly preferred. In the case of a substrate holder with only one zone, the outer periphery can be regarded as the separating wall in the sense of the invention, which separates the one single zone from the surrounding area.

Vacuum substrate holders are one kind of substrate holder. The space between the substrate and the substrate holder is evacuated via the fixing elements, which are for the most part exclusively small holes, and the atmospheric pressure presses the substrate onto and fixes the substrate on the substrate holder. Initially, only individual holes were drilled in the substrate holder and thus formed very simple fixing elements. The entire region between the substrate and the substrate holder surface was evacuated. All fixing elements present were connected to the same vacuum line. When a vacuum was applied, a full-surface fixing of the substrate which was not controllable or regulatable locally thus arose.

As a result of the development of these substrate holders and the possibility of controlling individual fixing elements, it became possible to control or regulate the fixing in a locally resolved manner.

A further development of the substrate holder consisted in combining the fixing elements and zones with a stud substrate holder (engl.: pin chuck). A stud substrate holder is a substrate holder which has been milled out at a plurality of positions, in particular symmetrically distributed. The milling-out does not take place over the whole surface, but preferably symmetrically along radial, azimuthal or rectangular lines. Elevations thus remain between these lines, relative to the milled-back area, which in the prior art are referred to as studs. By placing a substrate on these studs, a more or less complete support still takes place on the one hand, albeit by a very greatly reduced contact area. Furthermore, the intermediate spaces of the studs can be evacuated, which leads to evening-out of the contact pressure by the surrounding atmosphere. In particular, the stud density can also be varied as a function of the location, particularly as a function of the radius, in order to obtain a more homogeneous force effect on the substrate with the use of a plurality of fixing elements per zone. As a result of the milled-out studs, a recessed structure arises which is generally identical to a zone. Adjacent zones are delimited from one another by a separating wall. The separating wall is either material that has not been milled back or is an intentionally introduced, in particular polymer, seal. The separating wall encloses a zone completely and can also be regarded at the same time as a vacuum seal in the case of a vacuum substrate holder.

The problem in the prior art consists in the fact that adjacent zones or separated areas are in general evacuated with differing intensity, when the bonding wave is moving over the separating wall of a zone. A marked pressure gradient thus acts on the bonding wave, when the latter is moving over the separating walls of two zones. The pressure gradient leads to a marked distortion between the substrates.

In this regard, the problem also exists in the prior art that, even in the case of a substrate holder with only one zone, a pressure gradient between the single zone and the surrounding area exists. In this case, the separating wall of the substrate holder is at the same time the periphery, which separates the zone from the surrounding area. If a bonding wave runs on such a substrate holder at the edge, the same problem arises as in the case of passing over a separating wall which separates a plurality of zones from one another, which can distort the substrate areas close to the bonding wave.

It is the aim of the invention, therefore, at least partially to eliminate, in particular completely to eliminate the drawbacks stated in the prior art. It is a problem of the invention to specify an improved method and device for the bonding. Furthermore, it is an aim of the present invention to specify a method and a device, with which the bonding result can be improved, in particular the distortion between two substrates can be reduced.

### SUMMARY OF THE INVENTION

The present problem is solved with the features of the coordinated claims. Advantageous developments of the invention are given in the sub-claims. All combinations of at least two features specified in the description, in the claims and/or the drawings also fall within the scope of the invention. In the case of stated value ranges, values lying within the stated limits should also be deemed to be disclosed as limiting values and can be claimed in any combination.

Accordingly, the invention relates to a method for influencing a bonding wave during the bonding of a first substrate with a second substrate, wherein at least the first substrate is fixed on a first substrate holder with at least one zone and the at least one zone in each case comprises a separating element at least partially forming the substrate holder surface, and wherein the at least one separating element separates the at least one zone from a further zone or from the surrounding area of a first substrate holder, and wherein the at least one zone in each case comprises at least one fixing element and the at least one fixing element in each case provides a holding force for fixing the first substrate on the first substrate holder, wherein the method comprises at least the following steps: i) initiation of a bonding wave by contacting of the second substrate with the first substrate and subsequently ii) adapting the holding force of the at least one fixing element of the at least one zone to a holding force of a fixing element of a further zone located directly in front of the latter in a propagation direction of the bonding wave or to an ambient pressure of the surrounding area.

In other words, the at least one zone is controlled by adapting the holding forces of the fixing elements of the zone substrate holder, in such a way that the pressure gradient of the at least one zone in the direction of propagation of the bonding wave, in particular in the region of the separating element, as small as possible. In the case of the adaptation of the holding force of the at least one fixing element to the ambient pressure, in particular to the pressure of the last zone in the propagation direction, it is ensured that the atmospheric pressure, during the bonding at the moment the bonding wave passes over the separating wall at the edge of the substrate holder, is adapted to the holding force of the zone at the outer edge.

The pressure inside the at least one, in particular last, zone can be adapted to the ambient pressure. Since the adaptation of the pressure inside the zone can be brought about more quickly and efficiently than a pressure change in a large chamber or the surrounding area, an influence is advantageously exerted on the bonding wave. The holding force to the lower substrate in particular is reduced, or completely eliminated, so that it can spread unhindered at the edge.

The at least one zone preferably comprises a plurality of controllable fixing elements, wherein the holding forces can be varied in a targeted manner. The generation of a holding force gradient is thus enabled inside a zone, in order to be better able to control the advancing bonding wave still inside the at least one zone. Initiation of the bonding wave preferably takes place by central contacting of the second substrate with the first substrate, so that the propagation of the bonding wave takes place radially symmetrically.

Substrate holders with a plurality of zones, i.e. the at least one zone and at least one further zone, are particularly preferred. In the course of the following text, therefore, the embodiment of a substrate holder with a plurality of zones is often described, in which at least one separating wall is present which separates the two zones from one another. For the alternative embodiment of the method with a substrate holder with only one zone, in which the outermost separating wall at the same time represents the periphery of the substrate holder and in which no second zone is present, but instead the adjacent surrounding area, the holding force, preferably of the last zone or the outermost zone, is adapted, so that a particularly uniform crossing-over of the last or outermost separating wall is enabled. The separating wall can also be an inserted element, in particular a sealing lip. The separating wall does not therefore necessarily have to be produced from a milled-back region of the substrate holder, but can be a fitted component. In particular, the pressure in the outermost zone is adapted to the ambient pressure.

The zones can be divided into a plurality of segments perpendicular to the propagation direction of the bonding wave. A plurality of isosceles, trapezoidal segments can thus form a zone, wherein the segments again each preferably comprise at least one fixing element. Irrespective of the radial position, an adaptation of the bonding wave can thus advantageously take place simultaneously at a plurality of points along the preferably circular substrate holder. The adaptation takes place after the initiation of the bonding wave and preferably in each case in the region in which the bonding wave is propagating (the first and the second substrate are contacted or bonded). In this way, bonding that is particularly distortion-free is possible.

In a preferred embodiment of the method for the alignment, provision is made such that, during the adaptation in step ii), the ambient pressure is also adapted to the holding force of the fixing element of the at least one zone. In this regard, the prevailing atmospheric pressure or the ambient pressure is adapted in the bonding chamber. In this way, the holding force can advantageously be adapted indirectly in the at least one zone, since the ambient pressure acts on the first substrate.

In a preferred embodiment of the method for the alignment, provision is made such that the adaptation in step il) takes place in such a way that the holding force in the propagation direction of the bonding wave is equal in each case directly before and after the at least one separating element. In other words, by an adaptation of the holding force in the region of the separating elements at the time the bonding wave passes over, it is ensured that distortion-free bonding can also take place in the region of the zone transition. The holding force can also be continuously adapted. It is crucial that the large holding force difference of the zones desired for the regulation of the bonding wave is minimal immediately before and after the bonding wave crosses over the separating wall. In this way, a distortion in the region of the zone transitions can advantageously be ensured.

In a preferred embodiment of the method for the alignment, provision is made such that, after the initiation of the bonding wave in step i), the position of the bonding wave is ascertained continuously and the adaptation of the holding force of the at least one zone takes place in such a way that, during a crossing of the bonding wave over the at least one separating element, the holding force is equal before and after the at least one separating element. By determining the position of the bonding wave, the adaptation in step ii) can advantageously take place precisely at the time at which the bonding wave is moving over the separating elements. In this way, the desired holding force differences in regions outside the separating elements or between the latter can be implemented for the regulation of the bonding wave, without producing a distortion in the region of the zone transitions.

In a preferred embodiment of the method for the alignment, provision is made such that the at least one fixing element of the at least one zone is in each case constituted as a vacuum fixing and the at least one separating element separates the at least one zone fluidically from the further zone or the surrounding area. Particularly preferably, the substrate holder is a vacuum zone substrate holder, which is divided into a plurality of regulatable vacuum zones which are arranged symmetrically in the radial direction and in the propagation direction. The substrate arranged on the separating elements is thus sucked in and fixed. The holding force of the vacuum fixings is advantageously adjusted individually in each zone (or segment), since the latter are fluidically tight and thus suitable for a vacuum. In this way, the fixing element can act in the entire area and a full-surface regulation of the bonding wave takes place. The substrate holder can be rinsed in particular by an inert gas, preferably by helium. It is also conceivable that the vacuum lines are rinsed with the inert gas.

In a preferred embodiment of the method for the alignment, provision is made such that the adaptation in step ii) takes place by flooding or evacuation of the at least one zone or by flooding or evacuation of the surrounding area. In this way, the holding force can advantageously be provided easily, quickly and along a large area. In addition, the holding force can be adapted particularly quickly in the transition in the region of the zone transitions or in the region of the separating elements and subsequently can advantageously be quickly adjusted to the desired holding forces for the regulation of the bonding wave in the areas between the separating elements.

In a preferred embodiment of the method for the alignment, provision is made such that the adaptation in step ii) comprises the determination of a pressure difference between the at least one zone and the further zone or the surrounding area, wherein the pressure difference is evened out by the adaptation.

In this way, it can be ensured that a particularly small pressure gradient prevails before and after the separating element and the distortions during bonding are minimised. In addition, instead of being evacuated, the area lying before the separating element can advantageously be flooded.

In a preferred embodiment of the method for the alignment, provision is made such that a pressure of the at least one zone is adjusted to the pressure of the further zone. In this way, there is advantageously sufficient time to determine the position of the bonding wave precisely and then to adapt the pressure in the zone downstream in the propagation direction.

In an embodiment of the method for the alignment, provision is made such that the holding force of the at least one zone and of the further zone are adapted to one another in order to even out the pressure gradient. In this case, the further zone also comprises corresponding fixing elements with a variable holding force. In addition, in the case where the adaptation of the ambient pressure takes place to the last zone in the propagation direction, it can also take place simultaneously with that of the holding force of the at least one zone.

Furthermore, the invention relates to a device for influencing a bonding wave during the bonding of a first substrate with a second substrate, at least comprising a first substrate holder for fixing the first substrate with the at least one zone, wherein the at least one zone comprises at least one separating element forming at least partially a substrate holder surface of the first substrate holder, and at least one fixing element arranged in the at least one zone with a holding force for fixing the first substrate to the first substrate holder and a control unit for adapting the holding force of the at least one fixing element of the at least one zone, wherein the control unit is configured to adapt the holding force of the at least one fixing element of the at least one zone to a holding force of a fixing element of a further zone located directly before the latter in a propagation direction of the bonding wave or to an ambient pressure during advancing of the bonding wave.

The control unit is thus configured to even out the holding force of the at least one fixing element with the holding force of the zone upstream. With regard to the alternative, in which the holding force is adapted to the ambient pressure, the holding force of the last zone at the periphery of the substrate holder is in particular adapted depending on the ambient pressure. In other words, the zone substrate holder is provided with a plurality of controllable fixing elements, wherein the fixing elements are controlled in such a way that optimum holding forces are provided during bonding before and after a separating wall separating the zone, so that a distortion at the transition is reduced. The first substrate with the side facing away from the second substrate lies on the separating element at least partially forming the substrate holder surface. By controlling the holding forces before and after crossing over the separating wall, a bonding wave can be propagated particularly uniformly and unimpeded in the region of the separating wall. The undesired influence due to different holding forces before and after the separating wall on the bonding wave propagating in particular from the inside outwards is thus reduced. Holding forces acting with differing intensity between the zones may be desired in order to regulate the bonding wave. If a bonding process is not initiated from the centre, the outer zone with the fixing element with a variable holding force can also be arranged closer to the centre of the substrate holder. It is crucial that, in the direction of the bonding wave to be expected, the holding force of the following zone, in particular in the region of the separating element, can be adapted in order to even out the influence of the holding forces acting differently (before and after the separating wall). An advantageously small distortion in the region of the separating element can thus be ensured.

The dependence can also be determined on the basis of empirical or initial tests and adapted accordingly. The control unit is not limited to a mere control, but can also regulate the holding forces depending on further parameters (e.g. bonding wave position). The holding forces of the fixing elements can preferably be adjusted by the control units. In addition, the substrate holder preferably comprises a plurality of separating elements, which in turn can be separated into a plurality of segments along the preferably circular substrate holder. The segments of a zone distributed around the periphery are aligned in particular along the propagation direction, so that the, for example trapezoidal, segments become larger in the direction of the periphery. Overall, the stress and distortion, in particular in the region of the zone transitions or from the inner to the outer zone, can advantageously be minimised with the device. The control unit can also perform a regulation of the respective holding forces depending on further parameters.

In a preferred embodiment of the device for influencing a bonding wave during bonding, provision is made such that the device also comprises means for adapting the ambient pressure to the holding force of the at least one zone. In this way, the bonding wave can advantageously be indirectly influenced or the holding force can be adapted, since the ambient pressure acts on the first substrate. If the fixing elements are vacuum fixing elements which work with pressure, an evening-out of the pressures can take place, so that the run-out of the bonding wave takes place particularly gently.

In a preferred embodiment of the device for influencing a bonding wave during bonding, provision is made such that the control unit is configured in order to adapt the holding force of the at least one fixing element or the ambient pressure after contacting during bonding of the second substrate with the first substrate. The control unit is thus constituted such that the adaptation of the holding forces of the ambient pressure takes place only after the initiation of a bonding wave during bonding. In this way, the device or the control unit can carry out the adaptation taking account of the position, in particular on the basis of empirical data in the control unit, of the bonding wave.

In a preferred embodiment of the device for influencing a bonding wave during bonding, provision is made such that the control unit is configured to determine the holding force of the at least one fixing element of the at least one zone by means of a sensor. The sensor is preferably arranged in each case in the region of the separating elements in the at least one outer and/or inner zone. In addition, a sensor is preferably provided which ascertains the ambient pressure. In this way, the control unit can advantageously regulate the adaptation of the holding forces on the basis of real values, so that the distortion can be further reduced.

In a preferred embodiment of the device for influencing a bonding wave during bonding, provision is made such that the control unit is configured to keep the holding force of the at least one fixing element of the at least one zone and the holding force of at least one further fixing element of a further zone equal during the bonding of the first substrate with the second substrate. In this way, it is possible for the bonding wave to perform the transition from the inner to the outer zone particularly gently and distortion-free. Uniform holding forces can efficiently be adjusted uniformly in a plurality of zones in particular following one another. The bonding result is thus further improved and a small distortion is ensured during the crossing-over the separating wall.

In a preferred embodiment of the device for influencing the bonding wave during bonding, provision is made such that the control unit is configured to keep the holding force of the at least one fixing element of the at least one zone and the holding force of the at least one fixing element of the further zone equal in size directly in the region of the at least one separating element and at the time aw bonding wave runs over the at least one separating element. The position of the bonding wave is preferably determined by a measuring device, particularly preferably optically, and the time of the adaptation is adapted in the optimum manner to the position of the bonding wave. In this way, the regulation of the holding forces between the separating elements for influencing the bonding wave can advantageously be continued quickly after the separating elements are passed over. In addition, further improved bonding results, in particular in the region of the separating elements, can be achieved.

In a preferred embodiment of the device for influencing a bonding wave during bonding, provision is made such that at least one fixing element of the further zone and the at least one fixing element of the at least one zone are constituted as a vacuum fixings and the separating element separates the inner zone and the outer zone fluidically from one another. When a substrate is placed on the first substrate holder, a fixing of the substrate on the first substrate holder can thus advantageously be produced extensively in the entire zone area by under-pressure (compared to atmosphere or the surrounding area). This holding force can advantageously be changed quickly, precisely and in each zone. In addition, contamination of the first substrate can be kept small, since no contact with the substrate is required for the application of the force. The zones separated from one another fluidically and controlled by vacuum fixing elements are thus predestined for use in the device for influencing the bonding wave.

In a preferred embodiment of the device for influencing a bonding wave during bonding, provision is made such that the control unit is configured to keep a pressure difference between a pressure of the further zone and a pressure of the at least one zone as small as possible during bonding, preferably to keep them equal. The regulation of the pressure preferably takes place by means of pressure sensors arranged in the respective zones. During the bonding of the first substrate with the second substrate, uniform and distortion-free bonding, in particular in the region of the separating elements, can thus advantageously be created.

In a preferred embodiment of the device for influencing a bonding wave during bonding, provision is made such that the control unit is configured such that the means for changing the ambient pressure are means for adjusting the ambient pressure to the pressure of the at least one zone directly before and after the bonding wave passes over the at least one separating element. The aforementioned effects and advantage of the outer zone apply analogously to the further outer zone. By means of a plurality of zones in the direction of the propagation direction of the bonding wave, the bonding can be carried out particularly In the following, an outer zone is understood to mean the at least one zone or a zone downstream in the propagation direction of a bonding wave. An inner zone is a further zone or the last zone, if the ambient pressure is adjusted. The inner zone is a zone upstream in the propagation direction. The holding force of the downstream or the at least one zone is preferably adjusted to the holding forces of the upstream zone.

A particularly advantageous effect of the device and the method for influencing the bonding wave during bonding is that no distortions arise or only negligible distortions arise between the two substrates in the vicinity of the separating walls, which separates the zones from one another. A seamless, gentle and non-distorting crossing of the bonding wave front over the separating wall is thus possible. Especially in the region of the separating walls, the distortion is thus reduced and stresses in the bonded substrate stack are reduced.

A further aspect requires that the pressure has to be controlled and regulated continuously in the zones shortly before and/or during and/or after the bonding wave front passes over the separating wall. The pressure of a zone after the bonding wave or a zone in which the bonding wave is precisely located is preferably changed continuously, in such a way that it is adapted to the pressure of the zone into which the bonding wave is moving.

An aspect of the device and the method is that the bonding wave is influenced by control and regulation of the holding forces of the zones along the propagation direction of the initiated bonding wave in its progressing behaviour. By controlling/regulating at least one fixing element, in particular by the temporal adjustment of the pressure state in a zone, the speed or the acceleration of the bonding wave is adjusted in a targeted manner. In particular, a distortion-free, continuous and gentle passage of the advancing bonding wave over the separating walls of zones is enabled.

In the following process, idealised processes are assumed and described in order to represent an exemplary method for the bonding. In particular, it is assumed that the bonding wave propagates radially symmetrically, i.e. as circular as possible, from the contacting point to the periphery. This approach facilitates the description of the method, since mention can always generally be made of a bonding wave which has to be regulated. Generally, an asymmetric propagation of the bonding wave is also conceivable. All the methods, devices and approaches mentioned here, however, are regarded with a view to the fact that a bonding wave can generally be propagated in an anisotropic manner and therefore a regulation of the zones before and/or after a bonding wave section has to be considered, i.e. the regulation of the zones is generally adapted to the individual bonding wave sections, which have to pass over the separating wall at a certain position.

In the following text, mention is made of a regulation. A regulation is understood to mean a process in which a measurement signal is obtained for a first physical value and a second physical value is adjusted depending on a desired result. Conceivably, the position of a bonding wave would for example have to be measured (first physical value) and then the pressure in the zone before and/or the pressure in the zone after (second physical measurement value) the bonding wave would have to be adjusted, in such a way that a desired result (minimum distortion of the substrate or the substrates on the separating wall) is achieved.

In contrast, a control is understood to mean merely the ascertainment of a physical value, without a corresponding measurement signal. Thus, it may be that it is known on the basis of ascertained empirical data when a physical value must be adjusted to achieve a result. For example, it could be known how a bonding wave behaves with substrates always of the same type under the same initial and boundary conditions. In this case, the pressure could be controlled in the individual zones as a function of time, proceeding from the time of contacting, without the advancing bonding wave having to be measured.

The method and the device are described on the basis of vacuum substrate holders. This means that the fixings are vacuum fixings, in particular simple holes drilled in the substrate holder surface, which can be evacuated or flooded. It is also conceivable that other fixing elements such as electrostatic fixings, magnetic fixings are used. The latter are then also divided into zones and are suitable for adapting the respective holding forces. In this case, too, the fixing elements or their holding force are variable/adjustable. The term fixing element is therefore to be interpreted generally and relates not only, but preferably to vacuum fixings.

In a first process step of an exemplary method for influencing a bonding wave during bonding, a lower substrate is loaded onto a lower substrate holder and an upper substrate onto an upper substrate holder. The two substrates are preferably fixed with the fixing elements provided for the purpose.

In a second process step of an exemplary method for influencing a bonding wave during bonding, the two substrates are aligned with one another. The alignment preferably takes place with the alignment systems provided for the purpose. The alignment between the two substrates preferably takes place with the aid of alignment marks, which are located on the substrates. The methods and devices for the alignment are not dealt with in greater detail.

In third process step of the exemplary method for influencing a bonding wave during bonding, the two substrates are brought closer to one another. The distance between the two substrate surfaces to be bonded together is less than 10 mm, preferably less than 5 mm, still more preferably less than 1 mm, most preferably less than 0.1 mm, with utmost preference less than 0.01 mm.

It is also conceivable that the third process step is first carried out and only then the second.

In fourth process step of an exemplary method for influencing a bonding wave during bonding, at least one of the two substrates is deformed in such a way that contacting of the deformed substrate with the second substrate occurs. The contacting preferably takes place in as punctiform a manner as possible. The contacting takes place preferably also as centrically as possible. The contacting point is the start of the subsequently propagating bonding wave.

In a fifth process step of an exemplary method for influencing a bonding wave during bonding, the fixings are switched or regulated in such a way that at least one of the substrates can be deformed so that a bonding wave begins to run. The bonding wave is preferably initiated in the respective centre of the substrates and propagates radially symmetrically. With an advancing bonding wave, further fixings are switched or regulated in such a way that the bonding wave continuously moves towards the periphery.

The sixth process step of an exemplary method for influencing a bonding wave during bonding generally takes place repeatedly and always when a bonding wave section moves towards a separating wall between the zones. In this case, the pressure at in least one zone, in particular in a zone before and/or after the bonding wave section, is regulated. The bonding wave section is thus the, in particular, radially symmetrically propagating region in which the upper and the lower substrate are bonded. The regulation takes place in such a way that the bonding wave section produces a minimum distortion, in particular none at all, between the substrate areas which are located in the vicinity of the separating wall. For this purpose, the pressure in the zone before and/or in the zone after the bonding wave section is continuously regulated, so that the bonding wave section is not subject to a pressure gradient or only a In an embodiment of the device for influencing a bonding wave during bonding, the substrate holder comprises a plurality of fixing elements. The fixing elements can be controlled individually. The fixing elements are preferably vacuum fixings. With the aid of vacuum fixings, the contact pressure of the surrounding area on the substrate can be controlled very easily and very precisely. The fixing elements are part of a zone. A zone could generally comprise a plurality of fixing elements, in order to enable a finer control of the bonding wave inside a zone. Especially in the case of vacuum zones, a plurality of fixing elements serves to enable quicker evacuation of the zone to be carried out. By means of a plurality of fixing elements inside a zone, a greater volume flow of gas can be discharged and thus a quicker regulation can be performed. It would also be theoretically conceivable that the fixings inside a zone suck the gas off at different speeds. In this case, it would be possible to produce a pressure gradient inside a zone. However, it is better and more expedient to change the pressure inside a zone homogeneously and isotropically. The pressure inside a zone is thus preferably exclusively as a function of time and a plurality of fixing elements are preferably simultaneously switched, so that the pressure in a zone is regulated homogeneously and isotropically.

A device for bonding comprising at least one zone substrate holder, preferably at least one measuring device and at least one control unit. In the case of a regulation, the measuring device carries out the measurement of a physical parameter, for example the position determination of the bonding wave or at least a bonding wave section. The measuring device transmits these data to the control unit. The control unit evaluates the measurement and, depending on the result, determines the necessary physical parameters for controlling and/or regulating the fixing elements.

The measuring device is preferably optical systems for determining the bonding wave position. Sensors would however also be conceivable, which determine the position of a bonding wave electromagnetically. Proximity sensors for example would also be conceivable.

The curvature radius of a substrate at the point of the bonding wave is also of particular interest. In this regard, the control of the fixing elements can also take place depending on the curvature radius of the substrate in the region of the bonding wave.

The control unit is a microchip, computer, software or a combination thereof. In most cases, it will be software in a computer. The measurement signals pass via peripheral devices into the computer and are evaluated by the software. The software then regulates the fixing elements in the substrate holder via peripheral devices. The use of PID controllers would also be conceivable, in which the regulation has been programmed electronically.

### BRIEF DESCRIPTION OF THE DRAWINGS

Identical components or components with the same function are denoted by the same reference numbers in the figures. All sketches can be drawn enlarged for the purposes of representation, so that the figures do not have to have the proportions of the actual embodiments.

Further advantages, features and details of the invention emerge from the following description of preferred examples of embodiment and with the aid of the drawings. The latter show diagrammatically:

FIG. 1 is a plan view of an embodiment of the substrate holder of a device for influencing a bonding wave during bonding,

FIG. 2a is a first state of a sixth process step of an exemplary inventive method for influencing a bonding wave during bonding,

FIG. 2b a second state of a sixth process step of an exemplary inventive method for influencing a bonding wave during bonding,

FIG. 2c is a third state of a sixth process step of an exemplary inventive method for influencing a bonding wave during bonding, and

FIG. 2d is a fourth state of a sixth process step of an exemplary inventive method for influencing a bonding wave during bonding.

### DETAILED DESCRIPTION OF THE INVENTION

Identical components or components with the same function are denoted by the same reference numbers in the figures.

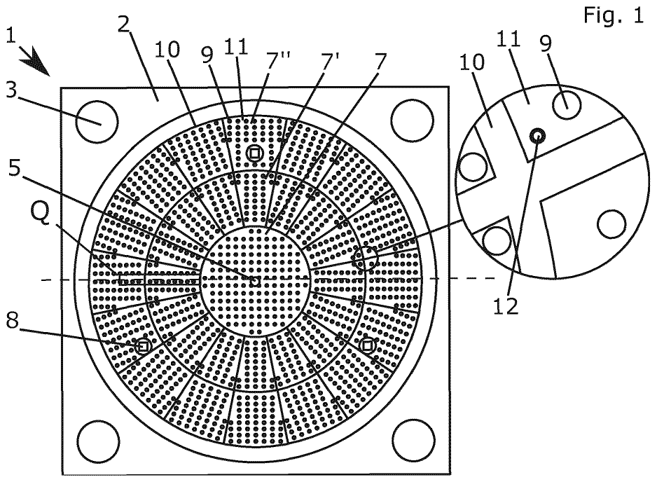

FIG. 1 shows the fixing surface of an embodiment of a substrate holder 1 of the device for bonding. Base body 2 can be mounted on the device with fixings 3. Substrate holder 1 comprises a plurality of zones 7, 7′, 7″ delimited in particular in the radial and azimuthal direction. In this example, zones 7, 7′, 7″ are delimited by separating walls 10. Separating walls 10 simply remain just like studs 9 in the milling-out of base body 2. Substrate holder 1 could also be constituted such that separating walls 10 are polymer seals or metal seals. A centric, radially symmetrical zone 7 can be seen in the figure. Furthermore, sixteen zones 7′, 7″ are each arranged radially around centric zone 7 along a first and a second circle.

Zones 7, 7′, 7″ are in particular set-back, preferably milled-out, recesses 11, in which studs 9 are located at several points. The pin surface of pins 9 is in particular congruent with the web surface of separating walls 10. Zones 7, 7′, 7″ in particular are constituted as a vacuum zones. Recesses 11 can be evacuated via a fixing means 12, in particular individually and, by the separation by separating walls 10, independently of one another. Fixing element 12 is simply a drill-hole in this simplest case, via which the space between studs 9 and thus zones 7, 7′, 7″ can be evacuated or flooded. If zones 7, 7′, 7″ also serve for the deformation, a fluid can also flow in via fixing means 12, which leads to an, in particular local, deformation of a fixed substrate.

Preferably located in the centre of substrate holder 1 is a deformation element 5, which can deform, in particular centrically, a fixed substrate. Studs 9 serve in particular for the reduction of the contact area of a fixed substrate 4, preferably to prevent contamination.

A plurality of sensors 8, in particular pressure sensors, can be located in zones 7, 7′, 7″ of substrate holder 1.

Region Q can also be seen in the figure, the cross-sectional of which will be represented in the further figures.

It is also clear to the expert in the field that a pressure can be defined as a force per unit area. Since the method for influencing a bonding wave with the aid of a vacuum substrate sample holder is described, and the zones are evacuated to produce a force on the substrate, it is advantageous to speak of pressures. Physical considerations with respect to forces and their effects must then be carried out according to the state-of-the-art.

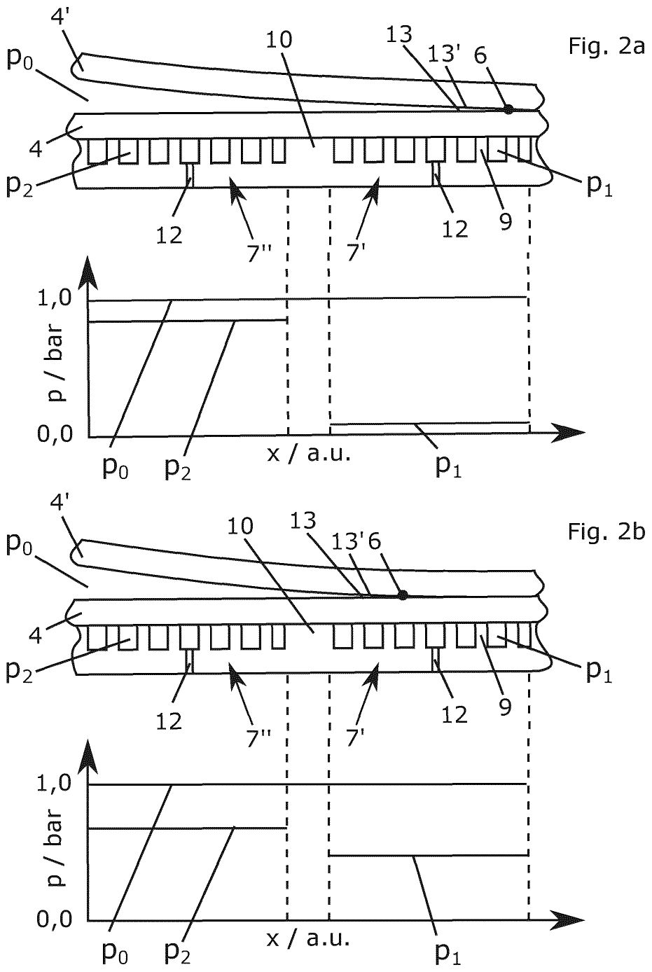

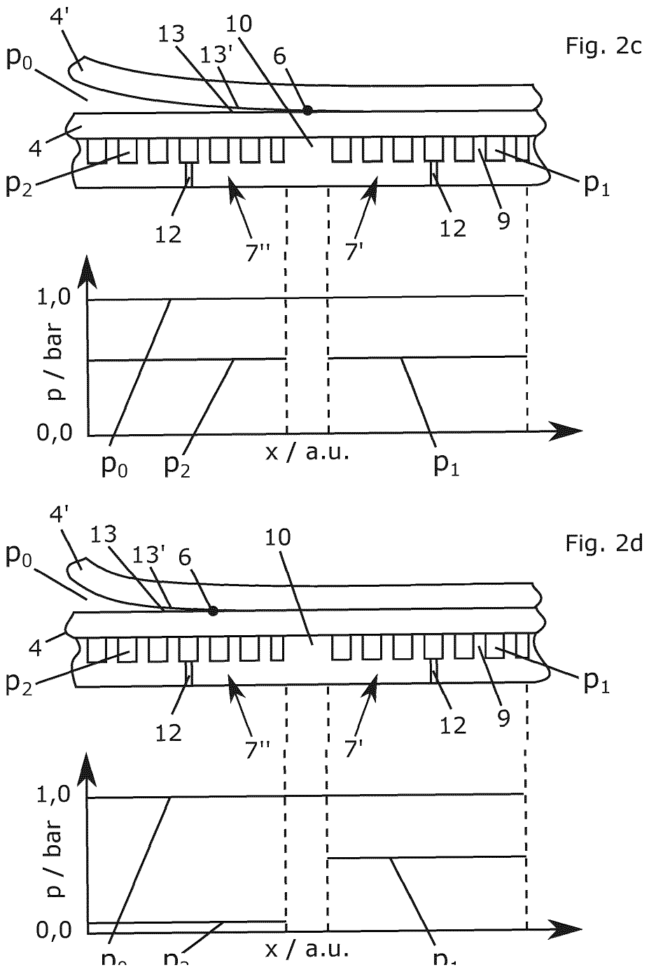

FIG. 2a shows a first state of a sixth process step of a method for influencing a bonding wave during bonding. The cross-section of a region Q (see FIG. 1) is represented by two zones 7′, 7″, and their separating wall 10. A lower substrate 4 lies on studs 9 and separating wall 10, an upper substrate 4′ is bonded with lower substrate 4 precisely in this section of the two zones 7′, 7″. Propagating bonding wave 6 can be seen. Bonding wave 6 is represented in cross-section solely as a dot. In the plan view, bonding wave 6 would be a completely closed curve, in particular and preferably a circle. Since the advancing bonding wave 6 is to take place in a controlled or regulated manner, the two zones 7′, 7″ generally have different pressures. In this figure, for example, pressure p1 in zone 7′ is selected low so as to be able to fix substrate region 13 of lower substrate 4 in a stronger and better way in the vicinity of bonding wave 6, in order that substrate region 13′ can bond with upper substrate 4′ as distortion-free as possible. Zone 7″ has a higher pressure p2, in particular close to the ambient pressure, in order that substrate regions 13, 13′, which are still farther from bonding wave 6, can still be adapted.

A pressure diagram is represented in the lower part of the figure. The abscissa shows the position in an arbitrary unit, preferably millimetres, the ordinate represents the pressure value. Three pressures are represented. On the one hand, external ambient pressure p0. In this case, it amounts to approx. 1 one bar.

It would also be conceivable for substrate holder 1 to be located in a chamber, in which the external pressure is raised. The ambient pressure would then be an over-pressure, relative to the atmosphere.

It would be conceivable for substrate holder 1 to be located in a chamber, in which the external pressure is reduced. The ambient pressure would then be an under-pressure relative to the atmosphere. This embodiment is of relevance particularly when the substrates have to be bonded in an environment with a lower pressure, in order for example to prevent or to reduce contamination.

In the subsequent text, it will be assumed that the device is open to the atmosphere and that ambient pressure p0 is the atmospheric pressure of approx. 1 bar.

Generally, ambient pressure p lies between 2 bar and 0.1 bar, preferably between 1.5 bar and 0.5 bar, still more preferably between 1.25 bar and 0.75 bar, most preferably between 1.10 bar and 0.90 bar, with utmost preference at precisely 1.0 bar.

The pressure in zone 7′ is denoted by p1. It is correspondingly low, because zone 7′ is evacuated very intensely. The pressure in zone 7″ is denoted by p2. It is higher than pressure p1 because zone 7″ is evacuated with less intensity.

Pressures p1, p2 generally always lie below ambient pressure p0. In very special embodiments, it is conceivable that at least one of the pressures lies above ambient pressure p0. In this case, substrate region 13 of substrate 4 beneath the zone in which the pressure lies above ambient pressure po would be raised.

Bonding wave 6 is still sufficiently far from zone 7″, so that the pressure difference between pressure p1 in zone 7′ and pressure p2 in zone 7″ still does not lead to any undesired distortion between the two substrate regions 13, 13′. In this process step, however, it is already detected, preferably with a lens, that bonding wave 6 is moving towards separating wall 10 and therefore very soon towards a marked change in pressure and therefore an intense effect will occur on bonding wave 6 and thus the bonding behaviour between substrate regions 13, 13′.

The values of pressures p1, p2 generally depend of course on the process and have to be ascertained by tests and/or simulations.

FIG. 2b shows a second state of a sixth process step of a method for influencing a bonding wave, in which bonding wave 6 has already advanced further. In order to ensure that substrate regions 13 of lower substrate 10 experience as mild a pressure effect as possible during the crossing of bonding wave 6 over separating wall 10, pressures p1 in zone 7′ and p2 in zone 7″ are already adjusted.

Since the transition from the first state according to FIG. 2a to the second state according to FIG. 2b naturally takes place continuously, i.e. whilst bonding wave 6 continuously advances, pressures p1, p2 are continuously adapted. The aim therefore is to ensure that substrate regions 13, 13′ are bonded together without or with only minimum errors.

The new values of pressures p1, p2 generally depend of course on the process and have to be ascertained by tests and/or simulations.

FIG. 2c shows a third state of a sixth process step of a method for influencing a bonding wave, in which bonding wave 6 is located on separating wall 10. In the prior art, pressures of differing intensity would act on a substrate region 13 from zone 7′ and zone 7″, which would lead to a defective bond between substrate regions 13 and 13′. By the adaptation of the holding forces or by the regulation of pressures p1, p2 in zones 7′, 7″, an optimum bonding process between substrate regions 13, 13′ is possible.

The values of pressures p1, p2 again generally depend of course on the process and have to be ascertained by tests and/all simulations. It is thus not necessarily the case that pressures p1, p2, as shown by way of example in the representation, have to be the same, but rather they have to be adjusted so that the two substrate regions 13, 13′ are bonded together in the most optimum manner possible. Bonded in the optimum manner means that any structures on the substrate surfaces in substrate regions 13, 13′ are bonded correctly aligned with one another.

FIG. 2d shows a fourth state of a sixth process step of a method, in which bonding wave 6 has moved over separating wall 10. Substrate regions 13, 13′ are now in new zone 7″. Pressure p2 in zone 7″, by way of example in this embodiment, could have been adjusted again to a very low value, in order to fix lower substrate 10, while bonding wave 6 advances towards the end of zone 7″. The new values of pressures p1, p2 again generally depend on the process and have to be ascertained by tests and/or simulations.

The process represented in FIGS. 2a to 2d makes provision to switch fixing element 12 during the crossing of a bonding wave 6 over a separating wall 10 of two zones 7′, 7″, in such a way that the bond between the substrate regions 13, 13′ and thus in general between substrates 4, 4′ takes place in the optimum manner, i.e. so that the deviations between structures on substrates 4, 4′ lying opposite one another are minimal. In the special case of a vacuum substrate sample holder 1, this means that the pressure regulation in zones 7′, 7″ takes place in such a way that, during the crossing of bonding wave 6 over separating wall 10, substrate regions 13, 13′ experience as continuous, gentle a pressure transition as possible, i.e. pressures p1, p2 are as equal as possible and only deviate slightly from one another.

### LIST OF REFERENCE NUMBERS

1 Substrate holder
2 Base body
3 Fixings
4,4′ Substrate
5 Deformation element
6 Bonding wave
7,7,7″ Zone, inner zone, outer zone, further zone
8 Sensor
9 Stud
10 Separating element, separating wall
11 Recess
12 Fixing element
13, 13′ Substrate region
Q Cross-sectional region
p0 Atmospheric pressure
p1, p2 Pressure of the upstream zone/inner pressure, of the downstream zone/outer pressure

1. A method for influencing a bonding wave during bonding of a first substrate with a second substrate, at least the first being fixed on a first substrate holder with at least one zone, the at least one zone including at least one separating element that at least partially forms a surface of the first substrate holder,
the at least one separating element separating the at least one zone from a further zone or a surrounding area of the first substrate holder,
the at least one zone further including at least one fixing element, the at least one fixing element providing a holding force for fixing the first substrate on the first substrate holder,
the method comprising:
initiating a bonding wave by contacting the second substrate with the first substrate; and
adapting, after the initiating the bond wave, the holding force of the at least one fixing element of the at least one zone to one of,
a holding force of a fixing element of the further zone located directly in front of the at least one zone in a propagation direction of the bonding wav; and
an ambient pressure of the surrounding area.

2. The method according to claim 1, wherein, during the adapting the holding force, the ambient pressure is adapted to the holding force of the fixing element of the at least one zone.

3. The method according to claim 1, wherein the adapting the holding force takes place in such a way that the holding force in the propagation direction of the bonding wave is equal directly before and after the at least one separating element.

4. The method according to claim 1, wherein, after the initiating the bonding wave;
a position of the bonding wave is ascertained continuously, and
the adapting the holding force takes place in such a way that, during a crossing of the bonding wave over the at least one separating element, the holding force is equal before and after the at least one separating element.

5. The method according claim 1, wherein the at least one fixing element of the at least one zone is a vacuum fixing and
wherein the at least one separating element separates the least one zone fluidically from the further zone or the surrounding area.

6. The method according to claim 1, wherein the adapting the holding force takes place by flooding or evacuation of the at least one zone or the surrounding area.

7. The method according to claim 1, wherein the adapting the holding force comprises determining a pressure difference between the at least one zone and the further zone or the surrounding area, and
wherein the pressure difference is evened out by the adapting the holding force.

8. The method according to claim 1, wherein a pressure of the least one zone is adjusted to the pressure of the further zone.

9. A device for influencing a bonding wave during bonding of a first with a second substrate, comprising:
a first substrate holder for fixing the first substrate with at least one zone, the at least one zone comprising at least one separating element that least partially forms a surface of the first substrate holder;
at least one fixing element arranged in the at least one zone with a holding force for fixing the first substrate to the first substrate holder; and
a control unit for adapting the holding force of the at least one fixing element of the at least one zone,
wherein the control unit is configured to adapt the holding force of the at least one fixing element of the at least one zone to one of:
a holding force of at least one fixing element of a further zone located directly before the at least one zone in a propagation direction of the bonding wave; and
an ambient pressure during an advancing of the bonding wave.

10. The device according to claim 9, comprising means for adapting the ambient pressure to the holding force of the at least one zone.

11. The device according to claim 9, wherein the control unit is configured to keep the holding force of the at least one fixing element of the at least one zone and holding force of the at least one fixing element of the further zone equal during the bonding of the first substrate with the second substrate.

12. The device according to claim 9, wherein the control unit is configured to keep the holding force of the at least one fixing element of the at least one zone and the holding force of the at least one fixing element of the further zone equal in size directly in a region of the at least one separating element and at a time the bonding wave runs over the at least one separating element.

13. The device according to claim 9, wherein the at least one fixing element of the further zone and the at least one fixing element of the at least one zone are vacuum fixings and the at least one separating element separates the at least one zone and the further zone fluidically from one another.

14. The device according to claim 9, wherein the control unit is configured to keep a a pressure of the further zone and a pressure of the at least one zone equal during bonding.

15. The device according to 10, wherein the control unit is configured such that the means for adapting the ambient pressure adjusts the ambient pressure to a pressure of the at least one directly before and after the bonding wave passes over the at least one separating element.
